(19) United States
(12) Patent Application Publication
(10) Pub. No.: US 2008/0001277 A1
(43) Pub. Date: Jan. 3, 2008

(54) Semiconductor package system and method of improving heat dissipation of a semiconductor package

(76) Inventors: Tsrong Yi Wen, HsinDian City (TW); I-Ting Tsai, Kaohsiung City (TW); Enboa Wu, Irvine, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 11/479,390

(22) Filed: Jun. 30, 2006

(51) Int. Cl. H01L 23/24; H01L 23/34

(52) U.S. Cl. 257/687; 257/706; 257/E23.11

(57) ABSTRACT

A semiconductor package system which includes a base circuit board, a semiconductor package mounted on the base circuit board, and a heat dissipation component having a first contacting area for making a first connection with an upper portion of the semiconductor package and a second contacting area for making a second connection with the base circuit board is disclosed. A method of improving heat dissipation of a semiconductor package is also disclosed.

### BACKGROUND OF THE INVENTION

1. Field of the Invention

The present invention relates to a semiconductor package system and a method of improving heat dissipation of a semiconductor package.

2. Description of the Related Art

In integrated circuit industry, packaging is one of the most important features. Packaging dominates the efficiency and reliability of the electronic products, especially high-end products. In order to meet the trend of lighter, thinner, shorter and smaller packages, better thermal performance of the package needs to be achieved.

Ball grid array (“BGA”) is the most well known high-end package. It has a plurality of solder balls or bumps for electrically connecting the semiconductor device to the substrate and printed circuit board (“PCB”). It also transfers the energy, i.e. heat, from the semiconductor device to the PCB. The PCB, having a large surface area, acts as a heat sink for heat dissipation. The plurality of solder balls is one major path to dissipate the heat. Another path is from the periphery, especially the top surface, of the package to ambient air. However, with natural convection, the efficiency of heat dissipation is very low. FIG. 1 shows a prior art (U.S. Pat. No. 6,882,041 B1) BGA package in which a metal cap 100 is provided on top of an integrated circuit device 330 covered by epoxy encapsulant material 340 such that heat generated from the integrated circuit device 330 can be dissipated through the metal cap 100.

A BGA package usually utilizes organic substrate such as Bismaleimide Triazine(“BT”) material as the electrical connection base. This non-electrical conductive material has poor thermal conductivity. Although the traditional metal cap provides an efficient way to conduct heat from package to substrate, it is not enough if the power is getting higher. U.S. Pat. No. 6,534,860 to Turner disclosed a thermal transfer plate (TTP) which has one or more “reference protrusions” to ensure that the gap between the TTP and the top surface of the semiconductor chip is kept at a certain optimal size for heat dissipation. The purpose of the invention is to substantially eliminate tolerance accumulations which plague the design of electrical assemblies. The way such a TTP dissipates heat is substantially through the plate's larger surface areas to the air, not through the feet to the base circuit board. The TTP's foot has a spring and stand-off which is secured through an aperture in the base circuit board, obviously an insufficient connection to conduct heat. Therefore, there is a need to produce a semiconductor package system with better heat dissipation and higher thermal efficiency.

The above description of the background is provided to aid in understanding the invention, but is not admitted to describe or constitute pertinent prior art to the invention, or consider the prior art as material to the patentability of the claims of the present application.

### SUMMARY OF THE INVENTION

According to one aspect of the invention, there is provided a semiconductor package system having (a) a base circuit board; (b) a semiconductor package having an upper portion and a lower portion, being situated in a position so that the upper portion is distal to the base circuit board while the lower portion is proximal to the base circuit board and connected to the base circuit board; and (c) a heat dissipation component having a first contacting area making a first connection with the upper portion of the semiconductor package and a second contacting area making a second connection with the base circuit board; the first connection and second connection being highly thermally conductive; and at least the first connection being made with an adhesive.

The heat dissipation component may be made of a metallic or a non-metallic material or a combination of metallic or non-metallic materials. The adhesive may be an organic glue or an inorganic glue or a combination of an organic glue and inorganic glue.

In an embodiment, the second connection is made through a plurality of solder balls. In another embodiment, the second connection is made through a plurality of pin-and-socket connections.

The heat dissipation component may be in the form of a cap having a flange portion and a top portion where the flange portion and top portion define a cavity configured to receive a semiconductor package. The flange portion is connected to the base circuit board forming the second connection. The top portion is connected to the top surface of the semiconductor package forming the first connection.

In another embodiment, an additional heat sink may be provided on top of the heat dissipation component, or a fan may be provided to operate with the heat dissipation component

According to another aspect of the present invention, there is provided a method of improving heat dissipation of a semiconductor package having a top surface, a sidewall surface and a bottom surface which is connected to a base circuit board, the method including (a) providing a heat dissipation component having a first contacting area and a second contacting area; (b) connecting the first contacting area of the heat dissipation component with the top surface, the sidewall surface, or both, of the semiconductor package; and (c) connecting the second contacting area of the heat dissipation component with the circuit board.

In one embodiment, the heat dissipation component is in the form of a cap having a top portion which provides the first contacting area, and a flange portion which provides the second contacting area.

In one embodiment, the connecting process in step (b) is accomplished by using a glue which is organic, inorganic or combination thereof, and the connecting process in step (c) is accomplished through a plurality of solder balls.

In another embodiment, the connecting process in step (c) is accomplished through a plurality of pins and sockets.

The method may further include the step of providing a heat sink on top of the heat dissipation component, or providing a fan in operation with the heat dissipation component.

Although the invention is shown and described with respect to certain embodiments, it is obvious that equivalents and modifications will occur to others skilled in the art upon the reading and understanding of the specification. The present invention includes all such equivalents and modifications, and is limited only by the scope of the claims.

### BRIEF DESCRIPTION OF THE DRAWINGS

Specific embodiments of the invention will now be described by way of example with reference to the accompanying drawings wherein:

FIG. 1 is a schematic cross sectional view of a BGA package of the prior art;

FIG. 2 is a cross sectional view of a heat dissipation component in accordance with an embodiment of the present invention;

FIG. 3a is a perspective view of a heat dissipation component in accordance with a first embodiment of the present invention;

FIG. 3b is a perspective view of a heat dissipation component in accordance with a second embodiment of the present invention;

FIG. 3c is a perspective view of a heat dissipation component in accordance with a third embodiment of the present invention;

FIG. 4 is a schematic cross sectional view of a semiconductor package system utilizing solder ball connection;

FIG. 5 is a schematic cross sectional view of a semiconductor package system utilizing pin-and-socket connection;

FIG. 6 is a schematic cross sectional view of a semiconductor package system of FIG. 4 with an additional heat sink; and

FIG. 7 is a perspective view of a semiconductor package system in accordance with another embodiment of the present invention.

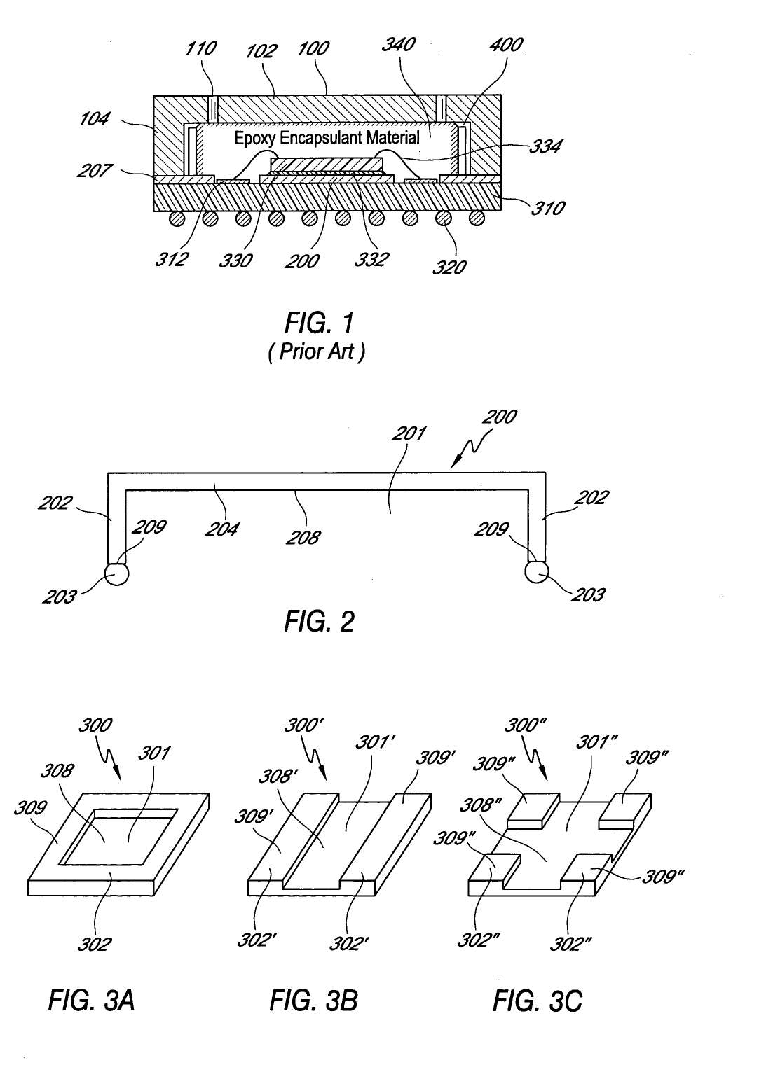

### DETAILED DESCRIPTION OF THE INVENTION

Reference will now be made in detail to certain embodiments of the invention, examples of which are also provided in the following description. Exemplary embodiments of the invention are described in detail, although it will be apparent to those skilled in the relevant art that some features that are not particularly important to an understanding of the invention may not be shown for the sake of clarity.

Furthermore, it should be understood that the invention is not limited to the precise embodiments described below and that various changes and modifications thereof may be effected by one skilled in the art without departing from the spirit or scope of the invention. For example, elements and/or features of different illustrative embodiments may be combined with each other and/or substituted for each other within the scope of this disclosure and appended claims.

In addition, improvements and modifications which may become apparent to persons of ordinary skill in the art after reading this disclosure, the drawings, and the appended claims are deemed within the spirit and scope of the present invention.

When the terms “upper”, “lower”, “top”, “bottom”, “outer”, “inner”, “upwardly”, or “downwardly”, or similar terms are used herein, it should be understood that these terms have reference only to the structure shown in the drawings as it would appear to a person viewing the drawings, and are utilized only to facilitate describing the invention.

The term “connect” or “connection”, when used herein to describe the relationship between two or more structures, means that such structures are secured or attached to each other either directly or indirectly through intervening structures.

Referring now to the drawings, in which like reference numerals represent like parts throughout the drawings, FIG. 2 is cross sectional view of a heat dissipation component 200 in accordance with an embodiment of the present invention. The heat dissipation component 200, generally in the shape of a cap, has a flange portion 202 and a top portion 204. The flange portion 202 and the top portion 204 together define a cavity 201 for receiving therein a semiconductor package.

The heat dissipation component 200 has a first contacting area 208 at the top portion 204 for making a first connection with a semiconductor package, and a second contacting area 209 at the flange portion 202 for making a second connection with a base circuit board.

The heat dissipation component 200 may be made initially from a block of metal or alloy material, such as copper, or aluminum etc. The cavity 201 on the heat dissipation component 200 can be formed by punching, milling, or etching.

FIG. 3a shows a heat dissipation component 300 in accordance with an embodiment of the present invention. The heat dissipation component 300 has a generally rectangular cavity 301 defined by a generally rectangular flange portion 302. The heat dissipation component 300 has a first contacting area 308 for making a first connection with a semiconductor package and a second contacting area 309 for making a second connection with a base circuit board, for example, through a plurality of solder balls 203 (see FIG. 2). Details of these first and second connections will be described later.

FIG. 3b shows a heat dissipation component 300′ in accordance with another embodiment of the present invention. The heat dissipation component 300′ has a trough or cavity 301′ defined by a pair of side flange portions 302′. According to the present embodiment, the heat dissipation component 300′ has a first contacting area 308′ for making a first connection with a semiconductor package and two second contacting areas 309′ defined by the pair of side flange portions 302′ for making second connections with a base circuit board.

FIG. 3c shows a heat dissipation component 300″ in accordance with a further embodiment of the present invention. The heat dissipation component 300″ has a cross-shaped cavity 301″ defined by four flange portions 302″ provided at the four corners of the heat dissipation component 300″ respectively. According to the illustrated embodiment, the heat dissipation component 300″ has a first contacting area 308″ for making a first connection with a semiconductor package and four second contacting areas 309″ for making second connections with a base circuit board.

Although a few embodiments of the heat dissipation component have been described, one skilled in the art would understand that the heat dissipation component could be of any other appropriate shapes and configurations.

For example, it has been shown that the first contacting area 208, 308, 308′, 308″ has a flat surface for mating with a flat top surface of a semiconductor package. However, it is contemplated that the first contacting area 208, 308, 308′, 308″ can be formed with a surface of any other shape conforming to the shape of the upper surface of a semiconductor package.

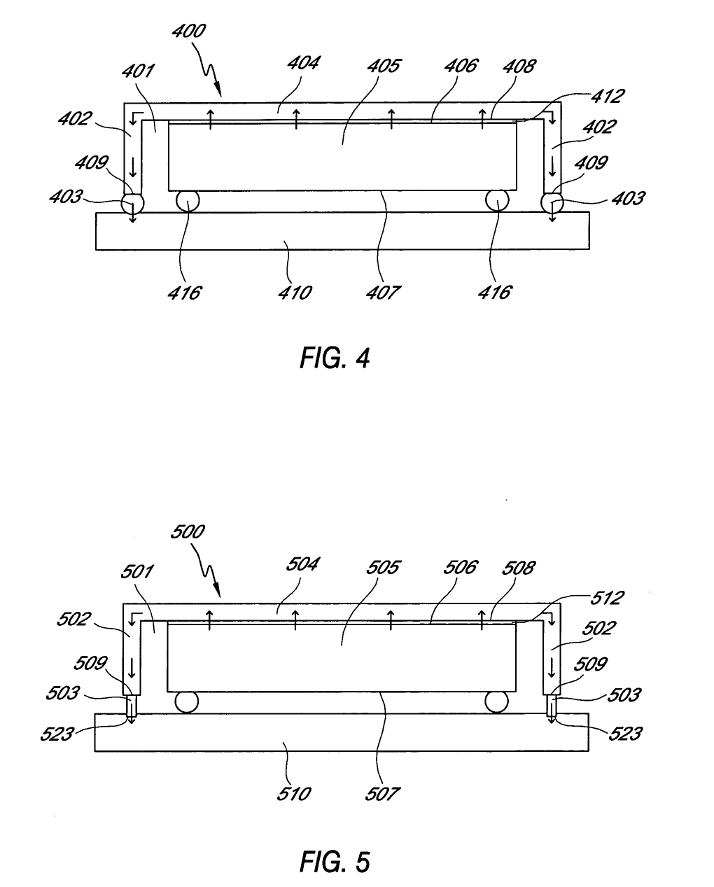

FIG. 4 is a schematic cross sectional view of a semiconductor package system in accordance with an embodiment of the present invention. The semiconductor package 405 has an upper portion 406 and a lower portion 407. The semiconductor package 405 may be situated in such a position that the upper portion 406 of the semiconductor package 405 is distal to a base circuit board 410 and that the lower portion 407 of the semiconductor package 405 is proximal and connected to the base circuit board 410.

The semiconductor package 405 can be a lead-frame package, a BGA/CSP package, a flip chip package, a wafer level CSP package, a 3D package, a system-in-package (SiP), a system-on-package (SoP), a direct chip attachment (DCA), a chip on board (COB), or other type of package. The semiconductor package 405 may also be a die, dice, module, or a group of modules. Depending on its usage, the semiconductor package 405 can include embedded or non-embedded, active or passive integrated circuits. The semiconductor package 405 is coupled to the base circuit board 410, for example, through an array of solder balls 416. The base circuit board 410 can be in the form of a printed circuit board made of an organic circuit board or a ceramic circuit board.

The heat dissipation component 400 is thermally conductive and may be made of a metallic, or non-metallic material, or a combination of metallic or non-metallic materials. The heat dissipation component 400 has a first contacting area 408 at a top portion 404 for making a first connection with the upper portion 406 of the semiconductor package 405, and a second contacting area 409 at a flange portion 402 for making a second connection with the base circuit board 410.

Details of the first and second connections will now be described. Preferably, the first and second connections are highly thermally conductive. According to the embodiment depicted in FIG. 4, the first connection is in the form of a thermal conductive adhesive 412, and the second connection is in the form of a plurality of solder balls 403.

The adhesive 412 may be an organic glue, or an inorganic glue, or a combination of an organic glue and an inorganic glue. The heat dissipation component 400 can be connected to the semiconductor package 405 by sparing, coating, or printing the adhesive 412 onto the contacting area 408 of the heat dissipation component 400 or the upper portion 406 of the semiconductor package 405. The adhesive 412 may take the form of a thin layer spreading evenly over the entire upper portion 406 of the semiconductor package 405 for better heat dissipation performance. The adhesive 412 can ensure a close thermal connection between the heat dissipation component 400 and the semiconductor package 405 for effective heat dissipation.

The second connection in the form of solder balls 403 can be employed to connect the heat dissipation component 400 to the base circuit board 410. The second connection can be made through surface contact between at least a portion of the second contacting area 409 of the heat dissipation component 405 and an area of the base circuit board 410.

The heat generated from the semiconductor package 405 can be dissipated through the adhesive 412 towards the top portion 404 and then the flange portion 402 of the heat dissipation component 400. The heat can further be dissipated from the flange portion 402 towards the solder balls 403 and finally to the base circuit board 410, which has a relatively large surface area for heat dissipation. The directions of heat dissipation are shown by the arrows.

FIG. 5 is a schematic cross sectional view of a semiconductor package system similar to FIG. 4 except that pin-and-socket connections are employed instead of solder balls. A plurality of thermally conductive metal pins 503 can be formed on the heat dissipation component 500. The pins 503 extend downwardly from the lower end of the flange portion 502 of the heat dissipation component 500. The heat dissipation component 500 can therefore be easily mounted on the base circuit board 510 by inserting the pins 503 into corresponding sockets 523 provided on the base circuit board 510.

Similarly, the heat generated from the semiconductor package 505 can be dissipated through the adhesive 512 towards the top portion 504 and then the flange portion 502 of the heat dissipation component 500. The heat can further be dissipated from the flange portion 502 towards the base circuit board 510 through the pins 503. The directions of heat dissipation are shown by the arrows.

One of the advantages of using pin and socket connections is that the heat dissipation component 500 can be produced as an individual product for a do-it-yourself component.

Although it has been shown that the heat dissipation component can be connected to the base circuit board by solder balls or pins and sockets, it is contemplated that other appropriate connecting means may be used. For example, the heat dissipation component can be connected to the base circuit board by a thermally conductive adhesive or glue.

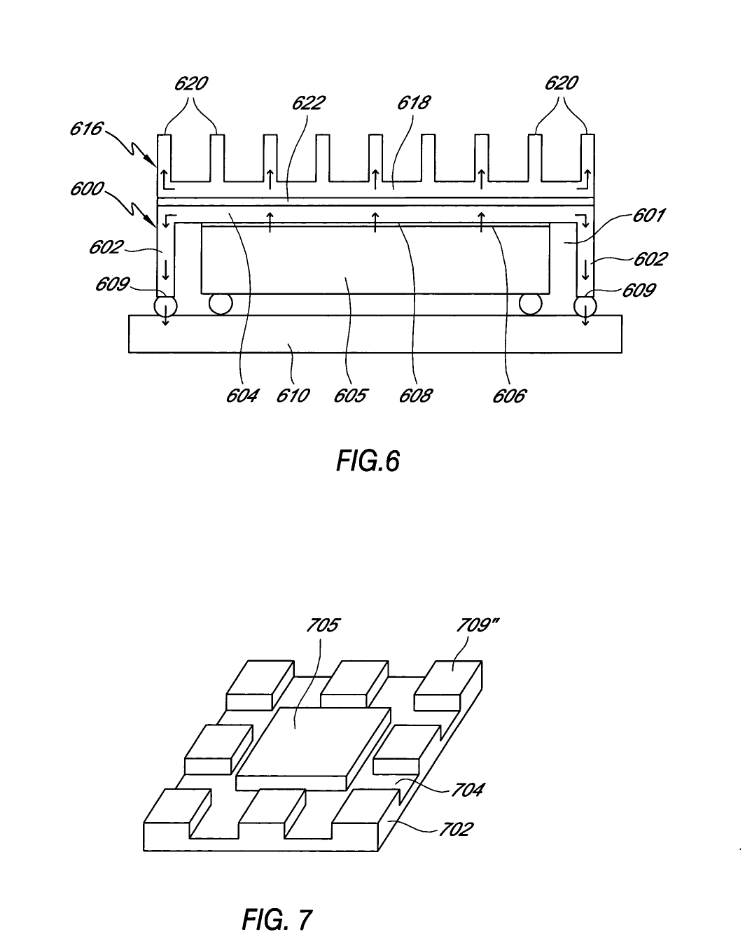

FIG. 6 is a schematic cross sectional view of a semiconductor package system in accordance with a further embodiment of the present invention. This semiconductor package system is substantially the same as the system of FIG. 4 except that an additional heat sink 616 is provided on top of a heat dissipation component 600. The heat sink 616 has a base 618 and a plurality of spaced apart heat dissipating fins 620 extending generally upwardly from the base 618. The base 618 is attached to a top portion 604 of the heat dissipation component 600 by a layer of thermally conductive adhesive 622. The adhesive 622 can be an organic glue, or inorganic glue, or combination of an organic glue and inorganic glue. The adhesive 622 can be formed on the heat sink 616 or the heat dissipation component 600 by sparing, coating, or printing.

The heat generated from the semiconductor package 605 can be dissipated through the adhesive 612 towards the top portion 604 of the heat dissipation component 600. The heat can further be dissipated from the top portion 604 of the heat dissipation component 600 towards the heat sink 616 through the adhesive 622. The directions of heat dissipation are shown by the arrows.

Although it has been shown that a heat sink 616 is adopted to serve as an additional heat-spreading component to enhance the heat dissipation performance of the semiconductor package, it is understood by one skilled in the art that other suitable heat spreading means such as a fan or a thermoelectric cooler can be used.

Although it has been described that one heat sink can be provided on top of the heat dissipation component, it is appreciated that more than one heat sink may be employed. The heat sink can be provided on the side of the heat dissipation component. The heat sink or heat dissipating fins may be formed integral with the heat dissipation component. The number and the arrangement of the fins provided on the heat sink may vary. The heat sink may also be provided with a contact area for making a connection with the base circuit board.

Although it has been described that the heat dissipation component is in the form of a cap and is in contact with a top surface of the semiconductor package, it is appreciated that the heat dissipation component can be manufactured as an integral part of the semiconductor package itself.

As shown in FIG. 7, for example, the semiconductor package and the heat dissipation component are integrated wherein the top portion 704 of the heat dissipation component also serves as the substrate of the semiconductor package 705, and the flange portion 702 is an extension of the substrate. The flange portion can be in the form of a closed sidewall (similar to 302 shown in FIG. 3a) or comprising a plurality of separated sidewall segments with a contact area 709″ (eight such segments shown in FIG. 7). All or some of the sidewall segments form connections with the base circuit board, whereby dissipating heat from the substrate. In general, substrate 704 and flange portion 702 are made of the same material, preferably, copper.

The semiconductor package system of the present invention can be easily manufactured because the semiconductor package, the heat dissipation component, and the heat sink can be connected together at a correct operating position by adhesive means without the necessity of accurate alignment. The employment of heat dissipation component and heat sink in a semiconductor package system is cheaper and quieter than conventional forced airflow cooler.

The present invention also provides a method of improving heat dissipation of a semiconductor package.

A heat dissipation component 200, 300, 300′, 300″, 400, 500, 600, generally in the shape of a cap, can be formed initially from a block of metal or alloy material such as copper or aluminum by punching, milling, or etching. The formed heat dissipation component has a flange portion 202, 302, 302′, 302″, 402, 502, 602 and a top portion 204, 404, 504, 604. The flange portion and the top portion together define a cavity 201, 301, 301′, 301″, 401, 501, 601 for receiving therein a semiconductor package 405, 505, 605.

The semiconductor package 405, 505, 605 is mounted on a base circuit board 410, 510, 610 in such a position that the upper portion of the semiconductor package is distal to the base circuit board and that the lower portion of the semiconductor package is proximal and coupled to the base circuit board by conventional means such as solder balls.

The heat dissipation component 400, 500, 600 can be positioned over the semiconductor package 405, 505, 605 in such a manner that a first contacting area 408, 508, 608 at the top portion 404, 504, 604 makes a first connection with the upper portion 406, 506, 606 of the semiconductor package, and a second contacting area 409, 509, 609 at the flange portion 402, 502, 602 makes a second connection with the base circuit board 410, 510, 610.

Referring to the embodiment illustrated in FIG. 4, the first connection may be a thin layer of thermal conductive adhesive 412, and the second connection may be a plurality of solder balls 403. The adhesive 412 can be in the form of an organic glue, or an inorganic glue, or combination of an organic glue and inorganic glue. The adhesive 412 can be formed on the contacting area 408 of the heat dissipation component 400 or on the upper surface 406 of the semiconductor package 405 by sparing, coating, or printing. The heat dissipation component 400 can then be connected to the semiconductor package 405 by the adhesive 412 without the necessity of accurate alignment.

The second connection can be in the form of a plurality of solder balls 403 arranged in an array or other pattern. The heat dissipation component 400 can be connected to the base circuit board 410 through the solder balls 403 utilizing surface mount technology (SMT).

The second connection can also be realized by pin and socket connection as depicted in FIG. 5, or a thermally conductive glue.

The heat dissipation component 400 may be made of a metallic, or a non-metallic material, or a combination of metallic or non-metallic materials, and is highly thermally conductive. The heat generated from the semiconductor package 405 can be dissipated through the adhesive 412 towards the top portion 404 and then the flange portion 402 of the heat dissipation component 400. The heat can further be dissipated from the flange portion 402 of the heat dissipation component 400 towards the base circuit board 410 through the solder balls 403 (or the pins 503 of FIG. 5). The directions of heat dissipation are shown by the arrows in the drawings. Of course, heat is further dissipated into the ambient air around the semiconductor package 405, the heat dissipation component 400, as well as the base circuit board 410.

To further enhance the heat dissipation performance, an additional heat sink 616 may be provided on the heat dissipation component 600, as illustrated in FIG. 6. The heat sink 616 has a base 618 and a plurality of spaced apart heat dissipating fins 620 extending upwardly from the base 618. A layer of thermally conductive adhesive 622 is formed on the heat sink 616 or the heat dissipation component 600 by sparing, coating, or printing. The heat sink 616 is then connected to the heat dissipation component 600 by the adhesive 622. The adhesive 622 can be an organic glue, or an inorganic glue, or a combination of an organic glue and inorganic glue.

Although it has been shown that an additional heat sink 616 is provided on top of the heat dissipation component 600 to enhance the heat dissipation performance of the semiconductor package, it is appreciated that a fan, or a thermoelectric cooler, or more heat sinks can be used, if necessary.

Although it has been shown and depicted in the drawings that the first contacting area 408, 508, 608 of the heat dissipation component 400, 500, 600 makes a first connection only with the upper surface 406, 506, 606 of the semiconductor package 405, 505, 605, it is understood that the heat dissipation component may make connection with the sidewall surface of the semiconductor package or both the top and sidewall surfaces of the semiconductor package.

While the present invention has been shown and described with particular references to a number of preferred embodiments thereof, it should be noted that various other changes or modifications may be made without departing from the scope of the present invention.

What is claimed is:

1. A semiconductor package system comprising:
a base circuit board;
a semiconductor package comprising an upper portion and a lower portion, being situated in a position so that said upper portion is distal to said base circuit board while said lower portion is proximal to said base circuit board and connected to said base circuit board; and
a heat dissipation component comprising a first contacting area forming a first connection with said upper portion of said semiconductor package and a second contacting area forming a second connection with said base circuit board; said first connection and second connection being thermally conductive; and at least said second connection being made with an adhesive.

2. The semiconductor package system of claim 1, wherein said semiconductor package comprises at least one of a die, a dice, a package, a module, and a group of modules.

3. The semiconductor package system of claim 2, wherein said base circuit board comprises a printed circuit board made of an organic circuit board or a ceramic circuit board.

4. The semiconductor package system of claim 3, wherein said adhesive comprises an organic glue, an inorganic glue, or a combination of an organic glue and an inorganic glue.

5. The semiconductor package system of claim 4, wherein said inorganic glue comprises solder.

6. The semiconductor package system of claim 1, wherein said second connection is made through surface contact between at least a portion of said second contacting area of said heat dissipation component and an area of said circuit board.

7. The semiconductor package system of claim 1, wherein said second connection is made through a plurality of solder balls.

8. The semiconductor package system of claim 1, wherein said semiconductor package is of a type selected from the group consisting of a lead-frame package, a BGA/CSP package, a flip chip package, a wafer level CSP package, a 3D package, a system-in-package (SiP), a system-on-package (SoP), a direct chip attachment (DCA), and a chip on board (COB).

9. The semiconductor package system of claim 8, wherein said semiconductor package comprises at least one of embedded integrated circuits, non-embedded integrated circuits, active integrated circuits, and passive integrated circuits.

10. The semiconductor package system of claim 1, wherein said heat dissipation component is thermally conductive and comprises a metallic material, a non-metallic material or a combination of metallic and non-metallic materials.

11. The semiconductor package system of claim 1, wherein said semiconductor package comprises an encircling wall surface and a top surface, and said heat dissipation component is in contact with said wall surface, said top surface, or both.

12. The semiconductor package system of claim 11, wherein said heat dissipation component further comprises a cap comprising a flange portion and a top portion where said flange portion and said top portion define a cavity configured to receive said semiconductor package, said flange portion being connected to said base circuit board forming said second connection, and said top portion being connected to said top surface of said semiconductor package forming said first connection.

13. The semiconductor package system of claim 12, wherein said flange portion is in a form of a closed sidewall or comprising a plurality of separated sidewall segments.

14. The semiconductor package system of claim 13, wherein said top portion of said heat dissipation component also serves as a substrate of said semiconductor package and said flange portion is an extension of said substrate and is connected to said base circuit board forming said second connection, said substrate and said flange portion being made of a same material.

15. The semiconductor package system of claim 1, further comprising a heat sink coupled to said heat dissipation component.

16. The semiconductor package system of claim 1, further comprising a fan operating with said heat dissipation component.

17. A method of improving heat dissipation of a semiconductor package having a top surface, a sidewall surface and a bottom surface which is connected to a base circuit board, the method comprising:
providing a heat dissipation component comprising a first contacting area and a second contacting area;
connecting said first contacting area of said heat dissipation component with said top surface, said sidewall surface, or both, of said semiconductor package; and
connecting said second contacting area of said heat dissipation component with said circuit board using an adhesive.

18. The method of claim 17, wherein said heat dissipation component comprises a cap having a top portion which provides said first contacting area and a flange portion which provides said second contacting area.

19. The method of claim 17, wherein connecting said first contacting area comprises using a glue which is organic, inorganic or a combination thereof.

20. The method of claim 17, wherein connecting said second contacting area comprises using a plurality of solder balls.

21. The method of claim 17 further comprising providing a heat sink on said heat dissipation component.

22. The method of claim 17 further comprising providing a fan operating with said heat dissipation component.
